(19) United States
(12) Patent Application Publication
(10) Pub. No.: US 2025/0081348 A1
(43) Pub. Date: Mar. 6, 2025

(54) BRIDGE PRINTED CIRCUIT BOARD EMBEDDED WITHIN ANOTHER PRINTED CIRCUIT BOARD

(71) Applicant: Intel Corporation, Santa Clara, CA (US)

(72) Inventors: Arumanayagam RAJASEKAR, Nagercoil (IN); Kesavan T, Hosur - Taluk (IN); Praveen YENUBARI, Hyderabad (IN); Velmurugan B, Attur (IN)

(21) Appl. No.: 18/462,220

(22) Filed: Sep. 6, 2023

(51) Int. Cl. H05K 1/14; H05K 1/02; H05K 1/11; H05K 3/46

(52) U.S. Cl. CPC H05K 1/142; H05K 1/0298; H05K 1/115; H05K 3/4644; H05K 2201/09518; H05K 2201/10159; H05K 2201/10734

(57) ABSTRACT

Embodiments herein relate to systems, apparatuses, techniques, or processes for forming a bridge PCB within one or more metal layers of a main PCB. The bridge PCB, which may be manufactured using mSAP techniques, may be formed between the first and the second metal layers of the main PCB and may be used for high speed signal routing between two dies, such as a system-on-chip die and a memory die, that are on the main PCB and coupled by the bridge PCB. Other embodiments may be described and/or claimed.

Embodiments of the present disclosure generally relate to package assemblies, and in particular package assemblies that include a printed circuit board embedded within a top layer of another printed circuit board.

### BACKGROUND

Continued reduction in end product size of mobile electronic devices such as smart phones and ultrabooks is a driving force for the development of reduced size system in package components, and for increased speed between processing units and memory.

### BRIEF DESCRIPTION OF THE DRAWINGS

FIG. 1 illustrates a cross-section side view of a system on chip (SOC) that is coupled with a memory chip using a printed circuit board (PCB) in a legacy implementation.

FIG. 2 illustrates a cross-section side view of an SOC that is coupled with a memory chip using a bridge PCB that is formed within another PCB, where the bridge PCB provides high speed access between the SOC and memory chip, in accordance with various embodiments.

FIG. 3 illustrates a cross-section side view diagram of a bridge PCB, in accordance with various embodiments.

FIG. 4 illustrates a top-down cross-section view of a bridge PCB, in accordance with various embodiments.

FIGS. 5A-5C illustrate a top-down views of an SOC that is coupled with a plurality of memory chips using a bridge PCB, in accordance with various embodiments.

FIGS. 6A-6B illustrate top-down cross-section views of layers within a bridge PCB, in accordance with various embodiments.

FIGS. 7A-7D illustrate stages in a manufacturing process for creating a bridge within a layer of a PCB, in accordance with various embodiments.

FIG. 8 illustrates an example of a process for embedding a bridge PCB within another PCB, in accordance with various embodiments.

FIG. 9 schematically illustrates a computing device, in accordance with embodiments.

### DETAILED DESCRIPTION

Embodiments of the present disclosure may generally relate to systems, apparatus, and/or processes directed to forming a PCB within one or more metal layers of another PCB, which may be referred to as a main PCB. In embodiments, the formed PCB may be referred to as a bridge PCB. In embodiments, the bridge PCB may be formed between two metal layers of the main PCB, and in particular may be formed between the first and the second metal layers of the main PCB.

In embodiments, the bridge PCB may be used to provide high-speed data connections between a first die and a second die that are on the main PCB and that may be both electrically coupled with the bridge PCB. In some embodiments, the first die may be a system on chip (SOC) and the second die may be a memory die. In embodiments, the memory dies may include a high-bandwidth memory (HBM), a double data rate (DDR) memory, or some other memory die. In embodiments, the bridge PCB may be used to route high speed I/O (HSIO) signals between the first die and the second die. In embodiments, the bridge PCB may be used to route only HSIO signals, where power may be routed through the first die and the second die through the metal layers within the main PCB.

In embodiments, the bridge PCB may be manufactured using a modified semi-additive process (mSAP) technique. In embodiments, the mSAP technique may involve a very thin copper layer that is first formed on the surface of PCB material. Any lines that do not need to be retained are covered with a coating, and then the required lines are exposed and are added by electroplating. Then, after removing the coating, the thin copper layer that has not been thickened is removed by micro-etching, and the required circuit is formed. This is in contrast to the subtractive process, where a PCB laminate is covered with a layer of copper foil, the lines that need to be retained are covered with the coating, and the exposed copper foil is removed by etching to form the required lines.

The mSAP technique may be used to achieve a smaller trace width, for example less than 25 μm, within the bridge PCB. These traces may be substantially smaller than the 50 μm trace width in FR4 PCB technologies. In embodiments, this allows a break out of more signals between the 0.4 mm pitch, and may allow a memory die to be placed closer to the SOC die.

In addition, embodiments may increase the maximum available memory speed between the SOC and the memory die. Maximum signal frequency depends on a variety of factors, including signal breakout from the first die and the second die, routing within the PCB, via structure within the main PCB, and overall routing length. In embodiments, by embedding a bridge PCB within the top two metal layers of the main PCB, these factors may be optimized for greater bandwidth performance.

In legacy implementations, where signals between a SOC and a memory die needed to be routed through multiple layers of a main PCB, greater routing length down into lower metal layers of the main PCB for high-speed signal routing is required. In addition, these legacy implementations also require metal layers above and below the high-speed signal routing layers to serve as reference planes to reduce electromagnetic interference to promote signal integrity through the legacy PCB. Furthermore, due to routing constraints, in legacy implementations the distance between the SOC and memory die needs to be increased to prevent HSIO signal interference experienced by the breakout between the first die and the legacy PCB and the second die in the legacy PCB.

In these legacy implementations, for memory on package SoC designs, substrate cost may be increased up to 30% due to memory die placement involving requiring additional area. Achieving a maximum capable memory speed is more critical with FR4 PCBs. The maximum frequency target depends on signal breakout, main routing, via structures to route down to signal layers, routing length and memory component placements in FR4 PCBs where the signal breakout between BGA balls adds impedance constraints as well as limits the amount of signal routing. Break out impedance, via, and the max length routing play vital role for defining the memory speed support due to signal integrity and manufacturing constraints.

In legacy implementations, a maximum of one signal can be made possible for breaking out between the BGA balls with the pitch of 0.4 mm. Therefore, for legacy implementations only based upon on Type-3/Type-4 Stack-up, signal breakout, component placement, layer count and signal routings are planned with signal integrity and fabrication constraints in mind. As a result, a minimum of four layers are required to route HSIO signals and provide reference planes for those signals. In addition, SOC to memory placement in legacy implementations also requires minimum 4 mm to allow the signal breakout and provide space for routing.

Embodiments described herein may also reduce the overall cost of the systems created with the bridge PCB implemented using a mSAP process. Because the resulting bridge PCB will have a fewer number of layers and multiple bridge PCBs can be formed on a single panel, the cost of producing a bridge PCB can be cheaper and more reliable than forming routing layers within a legacy PCB and drilling to connect the routing layers. In embodiments, embedding and mSAP-based bridge PCB into a FR4 PCB (motherboard) has the advantage of eliminating motherboard system integrity and core area constraints. In embodiments, the bridge PCB design may be used for any memory technology configurations.

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an ASIC, an electronic circuit, a processor (shared, dedicated, or group) and/or memory (shared, dedicated, or group) that execute one or more software or firmware programs, a combinational logic circuit, and/or other suitable components that provide the described functionality.

Various Figures herein may depict one or more layers of one or more package assemblies. The layers depicted herein are depicted as examples of relative positions of the layers of the different package assemblies. The layers are depicted for the purposes of explanation, and are not drawn to scale. Therefore, comparative sizes of layers should not be assumed from the Figures, and sizes, thicknesses, or dimensions may be assumed for some embodiments only where specifically indicated or discussed.

Various embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

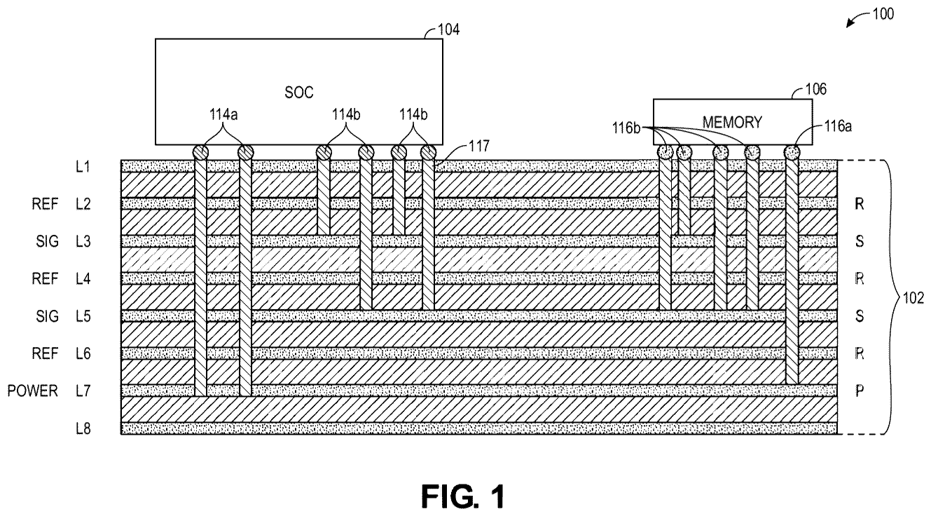

FIG. 1 illustrates a cross-section side view of a SOC that is coupled with a memory chip using a printed circuit board (PCB) in a legacy implementation. System 100 shows a legacy PCB 102 that includes 8 metal layers L1-L8. A system on chip (SOC) 104 is on the legacy PCB 102, and a memory 106 is also on the legacy PCB 102. In implementations, the SOC 104 is coupled with the legacy PCB 102 using solder balls 114a, 114b, and the memory 106 is coupled with the legacy PCB 102 using solder balls 116a, 116b.

In this legacy example, metal layers L2, L4, and L6 are reference planes, and metal layers L3, L5 are signal layers. Metal layer L7 a power plane. Therefore, to make the system 100 operational, solder balls 114a of SOC 104 are electrically coupled to the power plane L7 in the lower layer of the legacy PCB 102, and the solder ball 116a of the memory 106 is electrically coupled to the power plane L7.

In this implementation, the solder balls 114b of the SOC 104 that conduct the signals are electrically coupled with the signal layers L3 or L5. Similarly, the solder balls 116b of the memory 106 that conduct the signals are electrically coupled with the signal layers L3 or L5. Note that in these legacy implementations, the power plane L7 is furthest from the SOC 104 and the memory 106, to allow the signal layers L3, L5 to be closer and therefore reduce the distance between the SOC 104 and the memory 106 and therefore increase the speed of the signals.

As shown with respect to FIG. 1, to support to signal layers L3, L5, three reference planes L2, L4, L6 are required. Therefore, a total of five layers are required for signal routing within the PCB 102. In addition, this architecture for system 100 with the legacy PCB 102 provides both signal speed and routing constraints. For example, a distance between the SOC 104 and the memory 106 needs to be sufficiently separated, for example on the order of 4 mm, so that high-speed signals routed on L3 and L5 are at a sufficient distance to minimize interference between the SOC 104 or the memory 106. As a result, this increases the overall footprint required for the system 100. Also, this architecture also provides limits on memory and controller speed, for example 8 GHz performance may not be achievable due to the solder and routing structures within the legacy system 100.

In legacy implementations, the dielectric material between the metal layers L1-L8 may be a glass fiber/epoxy material, however different dielectric materials may be used. In addition, manufacturing and material cost in legacy system 100 is a large fraction of the overall cost, including routing cost that requires a vias 117 through the legacy PCB 102 to route the high-speed signals.

In a typical FR4 PCB pitches legacy PCB 102 has fabrication constraints to achieve the trace impedance, routing the signal between SOC 104 component pad that includes solder balls 114b, vias 117, and the like, and signal integrity guideline requirements. As a result, routing high speed memory signals between the SOC 104 and memory 106 may be difficult. Because of these signal integrity and fabrication constraints, placement of the memory 106 and the resulting increase in routing length add trace losses which degrade the signal quality. This leads to lower the speed bin and as a result is unable to achieve maximum capable memory data rates otherwise supported by the SOC 104 and the memory 106.

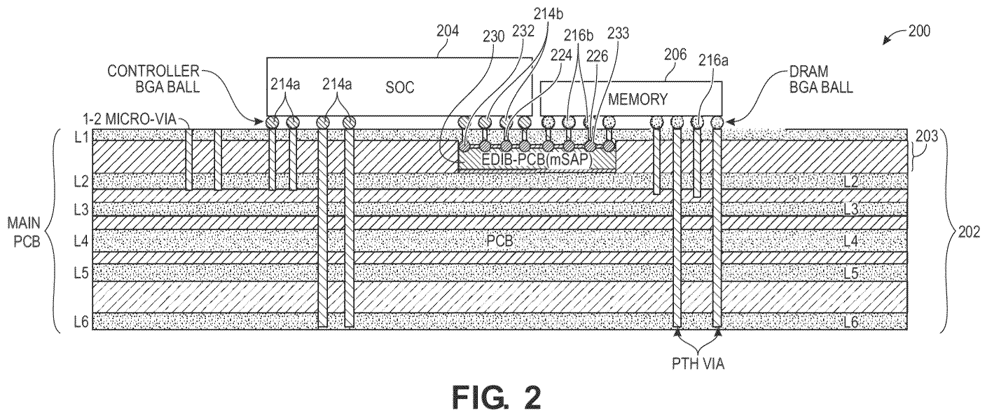

FIG. 2 illustrates a cross-section side view of an SOC that is coupled with a memory chip using a bridge PCB that is formed within another PCB, where the bridge PCB provides high speed access between the SOC and memory chip, in accordance with various embodiments. System 200 includes a main PCB 202, and a SOC 204 and a memory 206 on the main PCB 202, which may be similar to PCB 102, SOC 104, and memory 106 of FIG. 1.

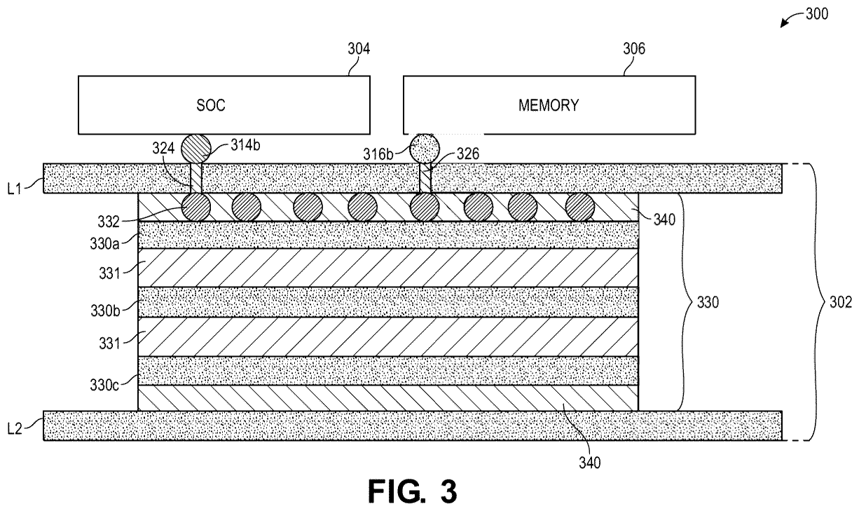

In embodiments, a layer 203, which may be between top metal layer L1 and metal layer L2, may include a bridge PCB 230. The bridge PCB 230 may be referred to as an Embedded Device Internet Bridge (EDIB). The bridge PCB 230 is explained in further detail with respect to FIG. 3 below. In embodiments, all or part of the HSIO routing between the SOC 204 and the memory 206 may occur through the bridge PCB 230. In embodiments, the bridge PCB 230 may be constructed using mSAP manufacturing techniques.

In embodiments, the SOC 204 may receive power, ground, controller signals, or other electrical connections through the solder balls 214a. In embodiments, the solder balls 214a may be electrically coupled with various metal layers, such as layers L2 or L6, within the main PCB 202. Similarly, the memory 206 may receive power, ground, controller signals, or other electrical connections through the solder balls 216a. In embodiments, the solder balls 216a may be electrically coupled with various metal layers, such as L2 or L6, within the main PCB 202.

The SOC 204 may be electrically coupled through solder balls 214b with the bridge PCB 230, and the memory 206 may be electrically coupled through solder balls 216b with the bridge PCB 230. In embodiments, the solder balls 214a, 214b, 216a, 216b may be similar to solder balls 114a, 114b, 116a, 116b of FIG. 1. In embodiments, some other technique for electrical connection other than solder balls 214a, 214b, 216a, 216b may be used, for example micro bumps or direct bonding (not shown).

In embodiments, the bridge PCB 230 may include solder balls 232, 233 that electrically couple with each other using routings within the bridge PCB 230 (not shown). In embodiments, the solder balls 214b may electrically couple with the solder balls 232 of the bridge PCB 230 using vias 224. In embodiments, the solder balls 216b may electrically couple with the solder balls 233 of the bridge PCB 230 using the vias 226.

In embodiments, the vias 224, 226 may be referred to as openings, and may be implemented as micro vias that may extend through the L1 layer of the main PCB 202, which also may be referred to as the top layer. In embodiments, an electrically conductive material may be placed into all or part of the vias 226 to provide an electrical connection between the solder balls 214b, 216b and the bridge PCB 230. In other embodiments, the bridge PCB 230 may be placed between other layers within the main PCB 202, for example between layers L2 and L3, or between layers L2 and L4, with a portion of L2 removed to accommodate the bridge PCB (not shown).

In embodiments, a thickness of the layer 203 between L1 and L2, may be based upon the thickness of the bridge PCB 230. In embodiments, pads (not shown) may be formed within the L1 layer of the main PCB 202 and used to couple with the SOC 204 and the memory 206. In some of these embodiments, the SOC 204 and the memory 206 may be coupled to the main PCB 202 using direct bonding or hybrid bonding.

In embodiments, the main PCB 202 may also be referred to as a main board, and may be fabricated with typical FR4 material and may be implemented as a FR4 “0-x-0+” stack up. Note that in embodiments, because of the bridge PCB 230 providing HSIO routing, an 8 layer PCB board is not needed and the layers may be reduced because signal routing layers within the legacy PCB, such as legacy PCB 102 of FIG. 1, are not needed. In some embodiments, an 8 layer legacy PCB may be reduced in embodiments to 6 layers, and a 10 layer legacy PCB may be reduced to an 8 layer PCB.

In embodiments discussed below, one or more bridge PCBs 230 may be associated with multiple SOC 204, and multiple memories 206. When fabricating the system 200, although there may be additional cost inserting the bridge PCB 230 into the layer 203, the resulting memory routing significantly benefits from high-speed signals routing through the bridge PCBs 230. For example, there may be 64 different signals for each channel (2 channels is 128), all at high-speed, and all routed through the bridge PCB 230. The result may be over 300 high speed signals.

FIG. 3 illustrates a cross-section side view diagram of a bridge PCB, in accordance with various embodiments. System 300, which may be similar to system 200 of FIG. 2, shows an SOC 304 and a memory 306, which may be a die, that is electrically coupled with a bridge PCB 330. SOC 304 is electrically coupled through solder ball 314b, through electrically conductive material within the via 324, that electrically couples with connection pads 332. The memory 306 is electrically coupled through solder ball 316b, through electrically conductive material within the via 326 that electrically couples with connection pads 332.

In embodiments, the connection pads 332 may be solder balls or micro bumps. The SOC 304, memory 306, bridge PCB 330, solder ball 314b, solder ball 316b, and vias 324, 326 may be similar to SOC 204, memory 206, bridge PCB 230, solder ball 214b, solder ball 216b, and the vias 224, 226 of FIG. 2.

The bridge PCB 330 may include a first metal layer 330a, a second metal layer 330b, and a third metal layer 330c. In embodiments, the metal layers 330a, 330b, 330c may be separated by a dielectric material 331, such as a prepeg material. In embodiments, the metal layers 330a, 330b, 330c may have a thickness of around 15 μm, and the dielectric material 331 may have a thickness of around 27 μm. In embodiments, the number of metal layers and/or thickness of the metal layers may vary. In embodiments, the thickness and/or material composition of the dielectric material 331 may also vary. The overall thickness of the bridge PCB 330 may be around 99 μm as shown, however this overall thickness may vary depending upon embodiments. In embodiments, the thickness may be low enough to allow the bridge PCB 330 to be placed between L1 and L2.

In embodiments, the metal layers 330a, 330b, 330c may have various configurations. For example, metal layer 330a and metal layer 330c may route HSIO signals, and metal layer 330b may be a ground plane. In some embodiments, layer L1 may also be a ground plane in order to improve signal integrity within metal layer 330a.

In embodiments, shielding 340, which may be a dielectric, may be placed on one or both sides of the bridge PCB 330. In embodiments, the shielding 340, in addition to providing electromagnetic interference shielding, may also provide additional strength to the bridge PCB 330. This additional strength may be useful while the vias 324, 326 through the metal layer L1 may be formed, for example, during drilling of the vias 324, 326. In embodiments, vias (not shown) may route signals between the connection pads 332 and the metal layers within the bridge PCB 330 that may be used for routing, for example metal layer 330a and metal layer 330c.

In embodiments, the bridge PCB 330 architecture as described with respect to system 300 may result in a 30% substrate cost-reduction as compared to legacy memory on package techniques, may achieve a maximum SOC-capable memory speed, provides flexibility to choose different memory configurations, provides a compact PCB core area, eliminates the PCB SI constraints due to reduced interference, reduces the main PCB layer count by at least two metal layers as discussed above, and enables a thinner system 300 implementation. In addition, embodiments using a bridge PCB 330 may result in a lower cost as compared to type 3 PCBs, because it has more layers Vs 0-x-0+ with the mSAP PCB.

In addition, as discussed above, in embodiments when the bridge PCB 330 is implemented using mSAP technology may enable a breakout of more than one signal between 0.4 mm BGA pitch and may enable the placement of memory 306 as close as ˜150 to 200 μm to the SOC 304. In embodiments, a 0.4 mm BGA pitch may be used for both SOC 304 and memory 306. Also, the memory signal BGA ball 316b may be arranged in such a way to easily breakout the signals and make the 1:1 connection with the SOC BGA ball 314b.

Use of mSAP techniques to create the bridge PCB 330 allows much finer routing structures down to 25 μm line/space. In addition, these techniques offer a significantly better conductor pattern geometry. For high-frequency applications, this may offer significant performance advantages.

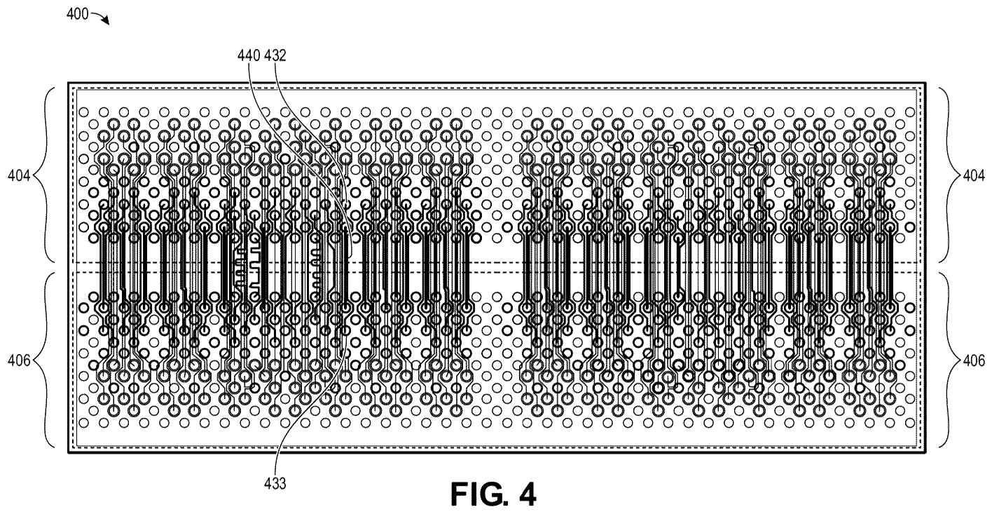

FIG. 4 illustrates a top-down cross-section view of a bridge PCB, in accordance with various embodiments. Bridge PCB 400 may show a cross-section view through connection pads 332 of FIG. 3 in a plane that is parallel to metal layer L1 of the main PCB 302. Connection pads 432 may be similar to connection pads 332 of FIG. 3. As shown, the region 404 may correspond to a region underneath the SOC 304 of FIG. 3, and the region 406 may correspond to a region underneath the memory 306 of FIG. 3.

Trace 440 shows an example trace between a connection pad 432 within region 404 that may be associated with a SOC such as SOC 204 of FIG. 2, to another connection pad 433 within region 406 that may be associated with a memory such as memory 206 of FIG. 2. In embodiments, trace 440 may route through metal layer 330a and/or metal layer 330c of FIG. 3.

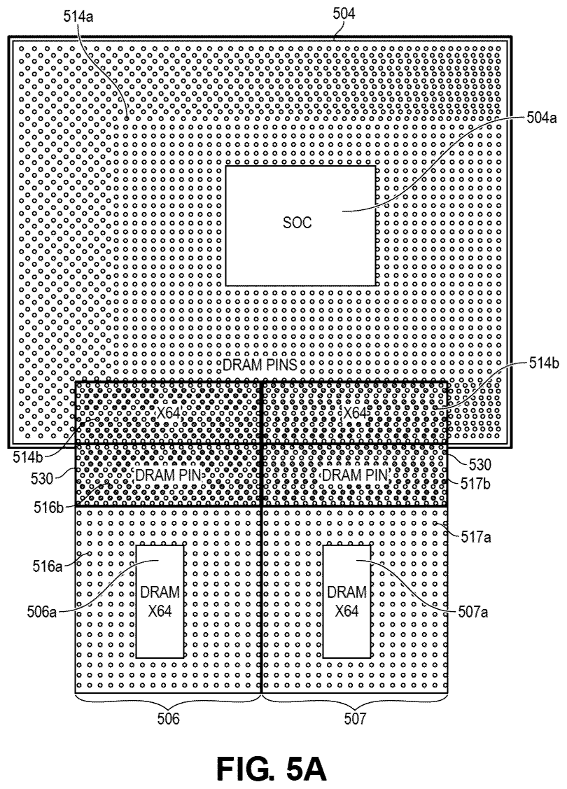

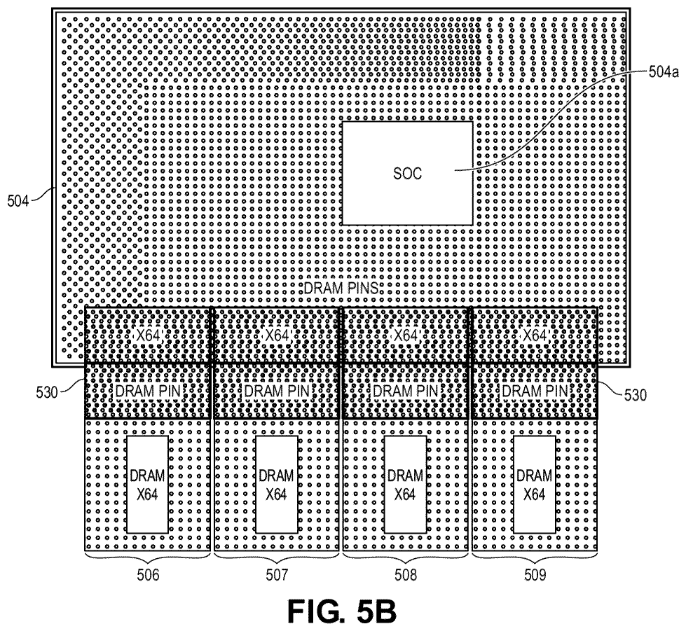

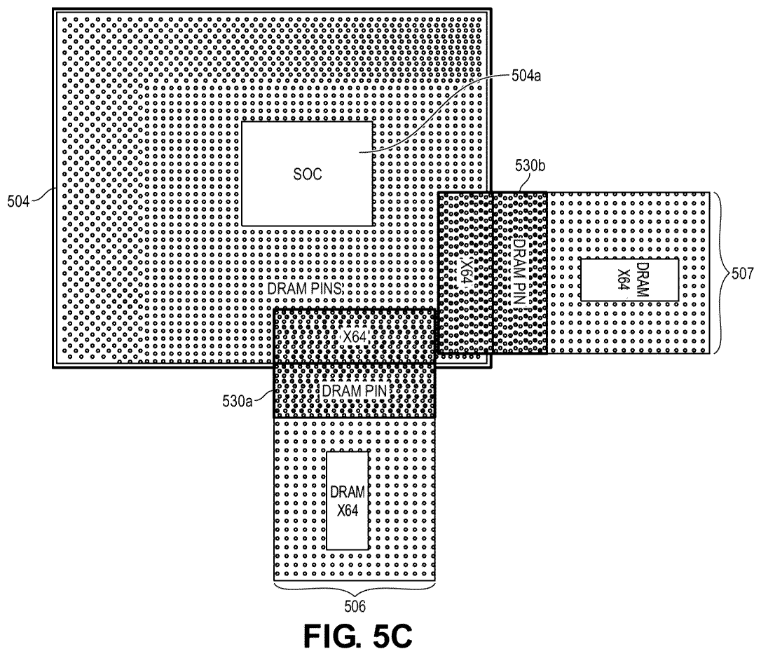

FIG. 5A-5C illustrate top-down views of an SOC that is coupled with a plurality of memory chips using a bridge PCB, in accordance with various embodiments. FIG. 5A shows a top-down view that includes an SOC 504 that includes SOC circuitry 504a that are electrically coupled with a plurality of solder balls 514a, 514b, which may be similar to solder balls 214a, 214b of FIG. 2. In embodiments, the solder balls 514a may be coupled with a main PCB (not shown), but may be similar to the main PCB 202 of FIG. 2.

FIG. 5A also shows two DRAMs 506, 507, which may be similar to memory 206 of FIG. 2. DRAM 506 may include circuitry 506a that is coupled with a plurality of solder balls 516a, 516b. DRAM 507 may include circuitry 507a that is coupled with a plurality of solder balls 517a, 517b. The plurality of solder balls 516a, 517a may be similar to solder balls 216a of FIG. 2, and the plurality of solder balls 516b, 517b may be similar to solder balls 216b of FIG. 2.

In embodiments, a bridge PCB 530, which may be similar to bridge PCB 230 of FIG. 2, may be underneath the SOC 504 and the DRAMs 506, 507. In embodiments, the solder balls 514b of the SOC 504 may be electrically coupled with a first set of solder balls (not shown) of the bridge PCB 530, but which may be similar to solder balls 232 of FIG. 2.

The solder balls 516b of the first DRAM 506 may be coupled with a first group of a second set of solder balls (not shown) of the bridge PCB 530, but which may be similar to solder balls 233 of FIG. 2. Similarly, the solder balls 517b of the second DRAM 507 may be coupled with a second group of a second set of solder balls (not shown) of the bridge PCB 530, but which may be similar to solder balls 233 of FIG. 2. In this way, the SOC 504 has a high-speed signal connection between the first DRAM 506 and the second DRAM 507.

FIG. 5B, which may be similar to FIG. 5A, shows a top-down view that includes an SOC 504 with circuitry 504a, that may be coupled with four DRAMs 506, 507, 508, 509 using a bridge PCB 530. In embodiments, the bridge PCB 530 may be an entire unit, or may be broken into multiple PCBs, with each serving one or more of the DRAMs 506, 507, 508, 509. Although shown here as adjacent to each other, the DRAMs 506, 507, 508, 509 may be different sizes, were different orientations, may be adjacent or separated from each other by uniform or a non-uniform distance.

FIG. 5C, which may be similar to FIG. 5A, shows a top-down view that includes an SOC 504 with circuitry 504a, that may be coupled with two DRAMs 506, 507 that may be attached to different sides of the SOC 504 using bridge PCBs 530a, 530b. In other embodiments, the DRAMs 506, 507 may be attached to a single bridge PCB (not shown) that is underneath both DRAMs 506, 507.

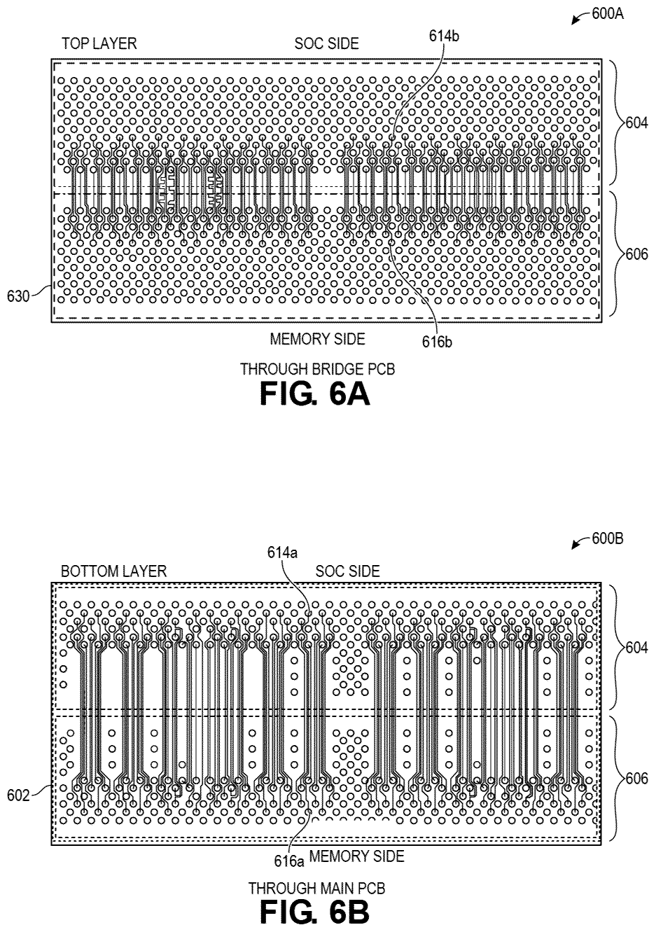

FIGS. 6A-6B illustrate top-down cross-section views of layers within a bridge PCB, in accordance with various embodiments. FIG. 6A illustrates a top layer 600A of a bridge PCB 630, which may be similar to bridge PCB 230 of FIG. 2, that shows an example of high-speed signal routing connections between a solder ball 614b of an SOC 604 and a solder ball 616b of a memory 606. In embodiments, the solder ball 614b, SOC 604, solder ball 616b, and memory 606 may be similar to solder ball 214b, SOC 204, solder ball 216b, and memory 206 of FIG. 2.

FIG. 6B illustrates a bottom layer 600B of a main PCB 602, which may be similar to the main PCB 202 of FIG. 2, that shows an example routing of power, ground, controller, and/or other lower speed connections between a solder ball 614a of an SOC 604 and solder balls 616a of the memory 606. In embodiments, the solder balls 614a, 616a may be similar to solder balls 214a, 216a of FIG. 2.

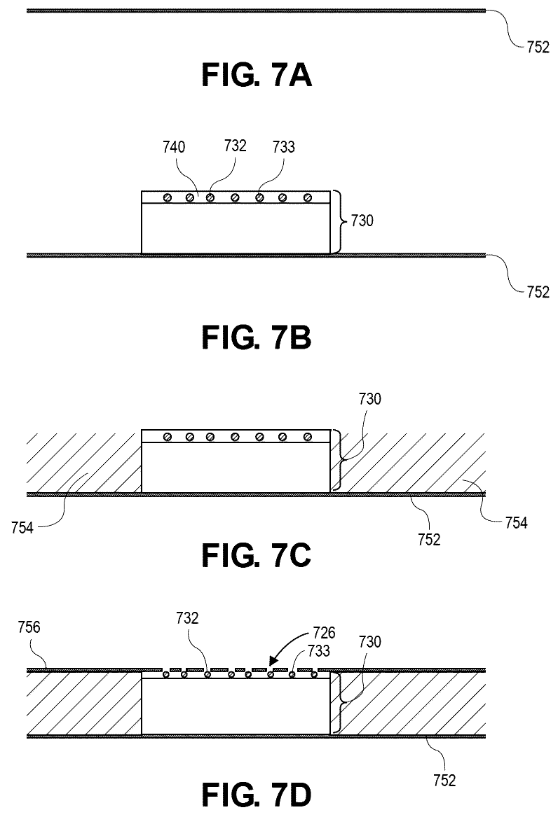

FIGS. 7A-7D illustrate stages in a manufacturing process for creating a bridge within a layer of a PCB, in accordance with various embodiments. FIG. 7A shows a cross-section side view of a stage in the manufacturing process where a metal layer 752 is provided. In embodiments, the metal layer 752 may be similar to layer L2 of FIG. 2.

FIG. 7B shows a cross-section side view of a bridge PCB 730, which may be similar to bridge PCB 230 of FIG. 2, that is formed on the metal layer 752. In embodiments, the bridge PCB 730 may be formed using mSAP techniques, and then placed upon the metal layer 752 after forming. In embodiments, solder balls 732, 733 may be placed on the top of the bridge PCB 730, and in embodiments may be at least partially encapsulated by a dielectric 740.

FIG. 7C shows a cross-section side view of a stage in the manufacturing process where a dielectric 754 is placed on top of the metal layer 752 and around the sides of the bridge PCB 730. In embodiments, the dielectric 754 may form an insulating layer that separates metal layers within a main PCB, such as the main PCB 202 of FIG. 2.

FIG. 7D shows a cross-section side view of a stage in the manufacturing process where a metal layer 756 is placed on top of the dielectric 754 and the bridge PCB 730. In embodiments, the metal layer 756 may be similar to metal layer L1 of the main PCB 202 of FIG. 2. In embodiments, opening 726 may be formed above the solder balls 732, 733 to provide an electrically conductive path to electrical connections to an SOC and a memory, for example SOC 204 and memory 206 of FIG. 2.

Subsequent stages in the process may include attaching metal layers and dielectric layers below metal layer 752. After these attached metal layers and dielectric layers are formed, drilling and/or etching processes may be performed to interconnect the attached metal layers and to provide electrical routing.

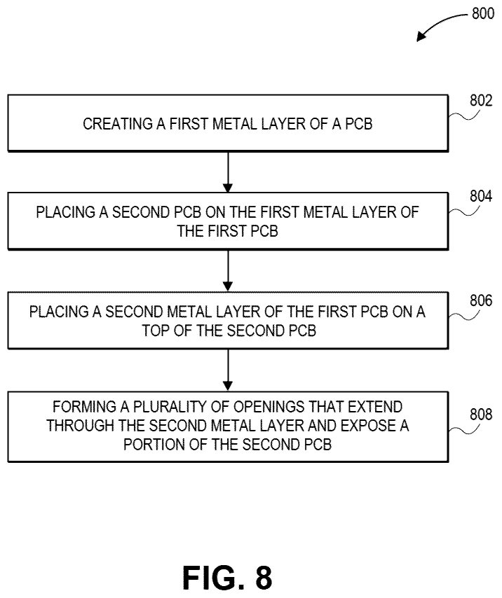

FIG. 8 illustrates an example of a process for embedding a bridge PCB within another PCB, in accordance with various embodiments. Process 800 may be performed using the processes, techniques, systems, or apparatus described herein, and in particular with respect to FIGS. 1-7D.

At block 802, the process may include creating a first metal layer of a first PCB. In embodiments, the first metal layer may be similar to layer L2 of FIG. 2, layer L2 of FIG. 3, or metal layer 752 of FIGS. 7A-7D. In embodiments, the first PCB may be similar to the main PCB 202 of FIG. 2, or the main PCB 302 of FIG. 3.

At block 804, the process may further include placing a second PCB on the first metal layer of the first PCB. In embodiments, the second PCB may be similar to bridge PCB 230 of FIG. 2, bridge PCB 330 of FIG. 3, bridge PCB 400 of FIG. 4, bridge PCB 530 of FIGS. 5A-5C, or bridge PCB 630 of FIG. 6A.

At block 806, the process may further include placing a second metal layer of the first PCB on a top of the second PCB. In embodiments, the second metal layer may be similar to layer L1 of FIG. 2, layer L1 of FIG. 3, or metal layer 756 of FIG. 7D.

At block 808, the process may further include forming a plurality of openings that extend through the second metal layer and expose a portion of the second PCB. In embodiments, the plurality of openings may be similar to vias 224, 226 of FIG. 2, vias 324, 326 of FIG. 3, or openings 726 of FIG. 7D.

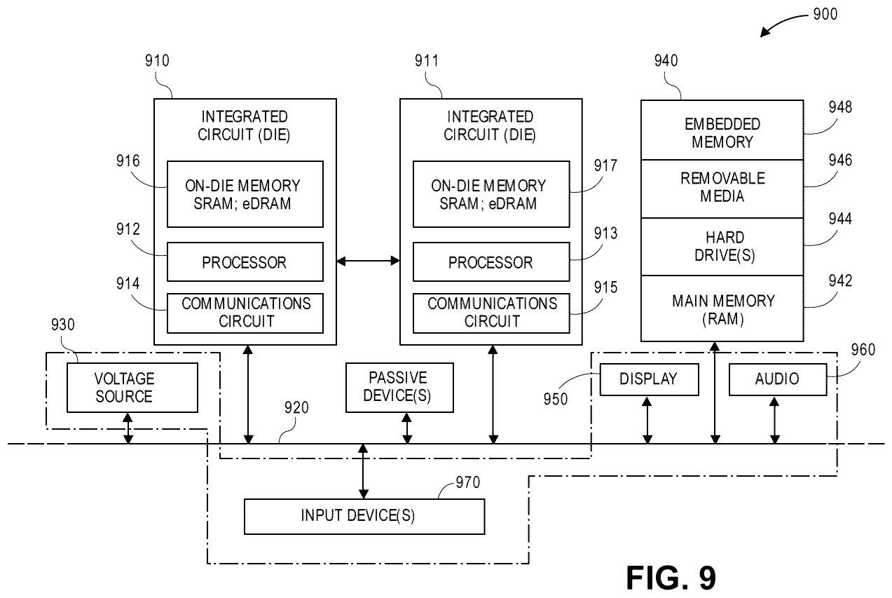

FIG. 9 is a schematic of a computer system 900, in accordance with an embodiment of the present disclosure. The computer system 900 (also referred to as the electronic system 900) as depicted can embody a bridge printed circuit board embedded within another printed circuit board, according to any of the several disclosed embodiments and their equivalents as set forth in this disclosure. The computer system 900 may be a mobile device such as a netbook computer. The computer system 900 may be a mobile device such as a wireless smart phone. The computer system 900 may be a desktop computer. The computer system 900 may be a hand-held reader. The computer system 900 may be a server system. The computer system 900 may be a supercomputer or high-performance computing system.

In an embodiment, the electronic system 900 is a computer system that includes a system bus 920 to electrically couple the various components of the electronic system 900. The system bus 920 is a single bus or any combination of busses according to various embodiments. The electronic system 900 includes a voltage source 930 that provides power to the integrated circuit 910. In some embodiments, the voltage source 930 supplies current to the integrated circuit 910 through the system bus 920.

The integrated circuit 910 is electrically coupled to the system bus 920 and includes any circuit, or combination of circuits according to an embodiment. In an embodiment, the integrated circuit 910 includes a processor 912 that can be of any type. As used herein, the processor 912 may mean any type of circuit such as, but not limited to, a microprocessor, a microcontroller, a graphics processor, a digital signal processor, or another processor. In an embodiment, the processor 912 includes, or is coupled with, a bridge printed circuit board embedded within another printed circuit board, as disclosed herein. In an embodiment, SRAM embodiments are found in memory caches of the processor. Other types of circuits that can be included in the integrated circuit 910 are a custom circuit or an application-specific integrated circuit (ASIC), such as a communications circuit 914 for use in wireless devices such as cellular telephones, smart phones, pagers, portable computers, two-way radios, and similar electronic systems, or a communications circuit for servers. In an embodiment, the integrated circuit 910 includes on-die memory 916 such as static random-access memory (SRAM). In an embodiment, the integrated circuit 910 includes embedded on-die memory 916 such as embedded dynamic random-access memory (eDRAM).

In an embodiment, the integrated circuit 910 is complemented with a subsequent integrated circuit 911. Useful embodiments include a dual processor 913 and a dual communications circuit 915 and dual on-die memory 917 such as SRAM. In an embodiment, the dual integrated circuit 910 includes embedded on-die memory 917 such as eDRAM.

In an embodiment, the electronic system 900 also includes an external memory 940 that in turn may include one or more memory elements suitable to the particular application, such as a main memory 942 in the form of RAM, one or more hard drives 944, and/or one or more drives that handle removable media 946, such as diskettes, compact disks (CDs), digital variable disks (DVDs), flash memory drives, and other removable media known in the art. The external memory 940 may also be embedded memory 948 such as the first die in a die stack, according to an embodiment.

In an embodiment, the electronic system 900 also includes a display device 950, an audio output 960. In an embodiment, the electronic system 900 includes an input device such as a controller 970 that may be a keyboard, mouse, trackball, game controller, microphone, voice-recognition device, or any other input device that inputs information into the electronic system 900. In an embodiment, an input device 970 is a camera. In an embodiment, an input device 970 is a digital sound recorder. In an embodiment, an input device 970 is a camera and a digital sound recorder.

As shown herein, the integrated circuit 910 can be implemented in a number of different embodiments, including a package substrate having a bridge printed circuit board embedded within another printed circuit board, according to any of the several disclosed embodiments and their equivalents, an electronic system, a computer system, one or more methods of fabricating an integrated circuit, and one or more methods of fabricating an electronic assembly that includes a package substrate having a bridge printed circuit board embedded within another printed circuit board, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having a bridge printed circuit board embedded within another printed circuit board embodiments and their equivalents. A foundation substrate may be included, as represented by the dashed line of FIG. 9. Passive devices may also be included, as is also depicted in FIG. 9.

Although certain embodiments have been illustrated and described herein for purposes of description, a wide variety of alternate and/or equivalent embodiments or implementations calculated to achieve the same purposes may be substituted for the embodiments shown and described without departing from the scope of the present disclosure. This application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second or third) for identified elements are used to distinguish between the elements, and do not indicate or imply a required or limited number of such elements, nor do they indicate a particular position or order of such elements unless otherwise specifically stated.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or to limit embodiments to the precise forms disclosed. While specific embodiments are described herein for illustrative purposes, various equivalent modifications are possible within the scope of the embodiments, as those skilled in the relevant art will recognize.

These modifications may be made to the embodiments in light of the above detailed description. The terms used in the following claims should not be construed to limit the embodiments to the specific implementations disclosed in the specification and the claims. The following claims are to be construed in accordance with established doctrines of claim interpretation.

### EXAMPLES

The following paragraphs describe examples of various embodiments.

Example 1 is an apparatus comprising: a first PCB that includes a plurality of metal layers; a second PCB within the first PCB, wherein the second PCB is between a first metal layer and a second metal layer of the plurality of metal layers of the first PCB; and wherein at least a portion of the first metal layer is above the second PCB, and wherein at least a portion of the second metal layer is below the second PCB.

Example 2 includes the apparatus of example 1, wherein there are no intervening metal layers in the first PCB between the first metal layer of the first PCB and the second metal layer of the first PCB.

Example 3 includes the apparatus of example 2, wherein the first metal layer is a top of the first PCB.

Example 4 includes the apparatus of examples 1, 2, or 3, wherein a first side of the second PCB includes a first insulator layer that is proximate to the first metal layer of the first PCB, and wherein a second side of the second PCB opposite the first side includes a second insulator layer that is proximate to the second metal layer of the first PCB.

Example 5 includes the apparatus of examples 1, 2, 3, or 4, wherein the second PCB is manufactured using a modified semi-additive process (mSAP).

Example 6 includes the apparatus of examples 1, 2, 3, 4, or 5, further comprising a dielectric material between the first metal layer and the second metal layer; and wherein the dielectric material is in direct physical contact with at least a portion of the second PCB.

Example 7 includes the apparatus of examples 1, 2, 3, 4, 5, or 6, further comprising one or more vias that extend through the first metal layer of the first PCB.

Example 8 includes the apparatus of example 7, further comprising electrically conductive material in the one or more vias that electrically couple with the second PCB.

Example 9 includes a system comprising: a first PCB that includes a plurality of metal layers; a second PCB within the first PCB, wherein the second PCB is between a first metal layer and a second metal layer of the plurality of metal layers of the first PCB, wherein at least a portion of the first metal layer is above the second PCB, and wherein at least a portion of the second metal layer is below the second PCB; a plurality of openings that extend through the first metal layer of the first PCB, wherein the plurality of openings are filled with electrically conductive material, and wherein the electrically conductive material in the plurality of openings are electrically coupled with the second PCB; a first die on the first metal layer of the first PCB, wherein the first die is electrically coupled with the electrically conductive material in a first group of the plurality of openings; a second die on the first metal layer of the first PCB, wherein the second die is electrically coupled with the electrically conductive material in a second group of the plurality of openings; and wherein the first die in the second die are electrically coupled through the second PCB.

Example 10 includes the system of example 9, wherein the second PCB includes a plurality of electrically conductive traces to electrically couple the first die in the second die, wherein the plurality of electrically conductive traces have a width of less than 25 μm.

Example 11 includes the system of examples 9 or 10, wherein the second PCB includes a ball grid array (BGA) on a side of the second PCB, wherein the BGA is electrically coupled with the electrically conductive material in the plurality of openings.

Example 12 includes the system of example 11, wherein the BGA has a pitch of 0.4 mm or less.

Example 13 includes the system of examples 9, 10, 11, or 12, wherein the first die is a system on chip (SOC), and wherein the second die is a memory die.

Example 14 includes the system of example 13, wherein a distance between an edge of the second die and an edge of the first die is less than 200 μm.

Example 15 includes the system of examples 9, 10, 11, 12, 13, or 14, wherein the second die is a plurality of second dies, wherein the second group of the plurality of openings is a plurality of second groups of the plurality of openings and wherein each of the plurality of second dies, and wherein each of the plurality of second dies is electrically coupled with the first die through the second PCB.

Example 16 includes the system of examples 9, 10, 11, 12, 13, 14, or 15, wherein high speed input/output (HSIO) signals are routed through the second PCB.

Example 17 includes the system of examples 9, 10, 11, 12, 13, 14, 15, or 16, wherein a total number of the plurality of metal layers of the first PCB is 6 metal layers or fewer.

Example 18 includes the system of examples 9, 10, 11, 12, 13, 14, 15, 16, or 17, wherein the second PCB is manufactured using a modified semi-additive process (mSAP).

Example 19 is a method comprising: creating a first metal layer of a first printed circuit board (PCB); placing a second PCB on the first metal layer of the first PCB; placing a second metal layer of the first PCB on a top of the second PCB; and forming a plurality of openings that extend through the second metal layer and expose a portion of the second PCB.

Example 20 includes the method of example 19, wherein placing the second PCB on the first metal layer of the first PCB further includes at least partially surrounding the second PCB with dielectric material, wherein the dielectric material is on the first metal layer of the first PCB.

What is claimed is:

1. An apparatus comprising:
a first printed circuit board (PCB) that includes a plurality of metal layers;
a second PCB within the first PCB, wherein the second PCB is between a first metal layer and a second metal layer of the plurality of metal layers of the first PCB; and
wherein at least a portion of the first metal layer is above the second PCB, and wherein at least a portion of the second metal layer is below the second PCB.

2. The apparatus of claim 1, wherein there are no intervening metal layers in the first PCB between the first metal layer of the first PCB and the second metal layer of the first PCB.

3. The apparatus of claim 2, wherein the first metal layer is a top of the first PCB.

4. The apparatus of claim 1, wherein a first side of the second PCB includes a first insulator layer that is proximate to the first metal layer of the first PCB, and wherein a second side of the second PCB opposite the first side includes a second insulator layer that is proximate to the second metal layer of the first PCB.

5. The apparatus of claim 1, wherein the second PCB is manufactured using a modified semi-additive process (mSAP).

6. The apparatus of claim 1, further comprising a dielectric material between the first metal layer and the second metal layer; and wherein the dielectric material is in direct physical contact with at least a portion of the second PCB.

7. The apparatus of claim 1, further comprising one or more vias that extend through the first metal layer of the first PCB.

8. The apparatus of claim 7, further comprising electrically conductive material in the one or more vias that electrically couple with the second PCB.

9. A system comprising:
a first printed circuit board (PCB) that includes a plurality of metal layers;
a second PCB within the first PCB, wherein the second PCB is between a first metal layer and a second metal layer of the plurality of metal layers of the first PCB, wherein at least a portion of the first metal layer is above the second PCB, and wherein at least a portion of the second metal layer is below the second PCB;
a plurality of openings that extend through the first metal layer of the first PCB, wherein the plurality of openings are filled with electrically conductive material, and wherein the electrically conductive material in the plurality of openings are electrically coupled with the second PCB;
a first die on the first metal layer of the first PCB, wherein the first die is electrically coupled with the electrically conductive material in a first group of the plurality of openings;
a second die on the first metal layer of the first PCB, wherein the second die is electrically coupled with the electrically conductive material in a second group of the plurality of openings; and
wherein the first die in the second die are electrically coupled through the second PCB.

10. The system of claim 9, wherein the second PCB includes a plurality of electrically conductive traces to electrically couple the first die in the second die, wherein the plurality of electrically conductive traces have a width of less than 25 μm.

11. The system of claim 9, wherein the second PCB includes a ball grid array (BGA) on a side of the second PCB, wherein the BGA is electrically coupled with the electrically conductive material in the plurality of openings.

12. The system of claim 11, wherein the BGA has a pitch of 0.4 mm or less.

13. The system of claim 9, wherein the first die is a system on chip (SOC), and wherein the second die is a memory die.

14. The system of claim 13, wherein a distance between an edge of the second die and an edge of the first die is less than 200 μm.

15. The system of claim 9, wherein the second die is a plurality of second dies, wherein the second group of the plurality of openings is a plurality of second groups of the plurality of openings and wherein each of the plurality of second dies, and wherein each of the plurality of second dies is electrically coupled with the first die through the second PCB.

16. The system of claim 9, wherein high speed input/output (HSIO) signals are routed through the second PCB.

17. The system of claim 9, wherein a total number of the plurality of metal layers of the first PCB is 6 metal layers or fewer.

18. The system of claim 9, wherein the second PCB is manufactured using a modified semi-additive process (mSAP).

19. A method comprising:
creating a first metal layer of a first printed circuit board (PCB);
placing a second PCB on the first metal layer of the first PCB;
placing a second metal layer of the first PCB on a top of the second PCB; and
forming a plurality of openings that extend through the second metal layer and expose a portion of the second PCB.

20. The method of claim 19, wherein placing the second PCB on the first metal layer of the first PCB further includes at least partially surrounding the second PCB with dielectric material, wherein the dielectric material is on the first metal layer of the first PCB.
